(19) United States
(12) Patent Application Publication
(10) Pub. No.: US 2011/0315985 A1
(43) Pub. Date: Dec. 29, 2011

(54) SENSOR-FITTED SUBSTRATE AND METHOD FOR PRODUCING SENSOR-FITTED SUBSTRATE

(75) Inventors: Masakazu Oba, Kanagawa (JP); Masaaki Oda, Chiba (JP)

(73) Assignees: ULVAC, INC., CHIGASAKI-SHI (JP); KELK LTD., HIRATSUKA-SHI (JP)

(21) Appl. No.: 13/148,530

(22) PCT Filed: Feb. 10, 2010
(86) PCT No.: PCT/JP2010/051967

§ 371 Date: Aug. 9, 2011

(30) Foreign Application Priority Data
Feb. 12, 2009 (JP) 2009-029997

(51) Int. Cl. H01L 21/3205; H01L 29/86; B82Y 99/00

(52) U.S. Cl. 257/48; 438/54; 977/773; 257/E21.294; 257/E29.325

(57) ABSTRACT

A sensor-fitted substrate allowing a sensor-fitted wafer for measuring the temperature or strain to be produced inexpensively, moreover, allowing measurements of the temperature or strain to be carried out with satisfactory accuracy, and a method for producing such a sensor-fitted substrate. An undercoat film is formed on the surface of a substrate, the film being configured, compared to when no undercoat film is formed, to allow the strength of close contact of a dispersed nano-particle ink with the substrate to be increased, the diffusion of the dispersed nano-particle ink into the substrate to be suppressed, and the growth of metal crystal particles contained in the dispersed nano-particle ink to be suppressed. A wiring pattern of the sensor is traced on the surface of the undercoat film of the substrate surface by using the dispersed nano-particle ink, and the dispersed nano-particle ink is baked and metalized.

### TECHNICAL FIELD

The present invention relates to a substrate such as a silicon wafer provided with a sensor for measuring the temperature or/and the strain of a substrate such as a silicon wafer in a high-temperature process, and to a method for producing the same.

### BACKGROUND ART

Present in an operation to produce a semiconductor device by performing treatments on a silicon wafer is a high-temperature process, which controls the temperature of a silicon wafer at a high temperature. In the high-temperature process, it is necessary to manage the temperature with good accuracy such as when heating each portion of the silicon wafer uniformly, for such purpose as improving the yield. Therefore, a sensor-fitted silicon wafer with a temperature sensor provided on the wafer is prepared, and prior to performing treatments on an actual silicon wafer, such as, at start time of a production line or at launch time of a production line, the temperature at each portion on the thermally sensor-fitted silicon wafer is measured with the temperature sensor in the same thermal environment as the actual silicon wafer, and the temperature controller is finely adjusted in such a way that each portion of the actual silicon wafer is heated uniformly.

In addition to this, it is desirable that a silicon wafer provided with a strain sensor on the wafer in addition to the temperature sensor is prepared, and at the time of temperature charge in the high-temperature process, the strain (heat strain) of the sensor-fitted silicon wafer is measured in addition to the temperature, and, from the result of this measurement, the temperature controller is finely adjusted by taking into account the warping, or the like, of the actual silicon wafer.

The sensors for measuring the temperature or the strain of a silicon wafer are sensors called thermocouples, resistance thermometers and strain gauges, which measure the temperature or the strain of a silicon wafer by measuring the thermal electromotive force or the resistance value of a metal and converting it into temperature.

Cited in the following are methods for producing conventional sensor-fitted silicon wafers:

A) A method for producing a sensor-fitted silicon wafer by attaching a sensor formed into a thin film over a silicon wafer using an adhesive.

B) A method for producing a sensor-fitted silicon wafer by forming a metal thin film constituting the sensor over a silicon wafer by vapor deposition, sputtering or the like (Patent Document 1 mentioned below, or the like).

C) Method for producing a sensor-fitted silicon wafer by forming a metal thin film constituting the sensor over a silicon wafer by the CVD method (Patent Document 2 mentioned below, or the like).

In addition, techniques using a dispersed nano-particle ink to trace a wiring pattern over a substrate have been developed in recent years.

D) Described in Patent Documents 3, 4 and 5 are inventions in which a glass layer serving as an insulation layer is formed over a stainless substrate and above this, a wiring pattern is traced using a dispersed nano-particle ink having silver as a main component to produce a strain sensor.
Patent Document 1: Japanese Patent Application Laid-open No. S62-139339
Patent Document 2: Japanese Patent Application Laid-open No. H08-306665
Patent Document 3: Japanese Patent Application Laid-open No. 2006-226751
Patent Document 4: Japanese Patent Application Laid-open No. 2006-242797
Patent Document 5: Japanese Patent Application Laid-open No. 2007-85993

### DISCLOSURE OF THE INVENTION

### Problems to be Solved by the Invention

Since the method of (A) described above uses an adhesive to attach a sensor to a silicon wafer, depending on the bonding state, warping, creep or drift of the sensor per se occurs readily, varying the measured values of temperature or strain and giving rise to errors, moreover, temperature measurements and strain measurements sometimes cannot be carried out accurately. In addition, for the methods of (B) and (C) described above, although problems such as those arising in the method of (A) described above do not occur, the equipment for forming a sensor on a silicon wafer becomes extensive, leading to high costs. Especially, in recent years, it has been necessary to form sensors on a silicon wafers with diameters of 300 mm or exceeding 300 mm, and producing sensor-fitted wafers inexpensively while fulfilling the required specs has been difficult. Supplementing further, in order for the measured values to fulfill the specs with a resistance thermometer using a material other than Pt for inexpensive production and a conventional production method to spread a meander wiring over the surface, it is necessary that the meander wiring unit has a larger surface area or that the meander wiring thickness becomes more of an ultra-thin film. If the surface area becomes large, the influence of the warping of the substrate per se becomes large, moreover, the use as a temperature sensor for controlling the in-plane temperature to uniformity is difficult. When the meander wiring is an ultra-thin film, the influence of Joule's heat at conduction time, concerns about the continuity of the thin film, and limitations on the method for joining the terminals for electric signal input/output and conductive wires become problematic.

The method of (D) described above is most definitely one with the purpose of forming an insulation layer for insulation between metals when tracing over a stainless substrate with a dispersed nano-particle ink having silver as a main component, and gives no explicit description regarding solving problems other than insulation between metals when tracing over a stainless substrate with a dispersed nano-particle ink.

The present invention was devised in view of such circumstances, and an object thereof is to allow sensor-fitted wafer for measuring temperature or strain to be produced inexpensively, moreover, to allow measurements of temperature or strain to be carried out with good accuracy, and furthermore, to solve many problems occurring when tracing over a substrate with a dispersed nano-particle ink.

### Means for Solving the Problems

The 1st invention is characterized in

a sensor-fitted substrate having a sensor over a substrate for measuring a temperature or/and strain of the substrate in a high-temperature process, wherein

the sensor measures a resistance value of a metal serving as a resistor which is converted into a temperature or/and strain, thereby measuring the temperature or/and strain of the substrate,

the substrate is a substrate where metals are diffused, the metals being contained in a dispersed nano-particle ink of nano-particles of any metal among Au, Ag, Pt, Ni and Cu or alloy nano-particles containing Pd or Cu or Si in Ag or a dispersed nano-particle ink in which Ag nano-particles and nano-particles of Pd or Cu or Si are mixed,

an undercoat film is formed on a surface of the substrate, the film being configured, compared to when no undercoat film is formed on the surface, to allow a strength of close contact of the dispersed nano-particle ink with the substrate to be increased, the diffusion of the dispersed nano-particle ink into the substrate to be suppressed, and the growth of metal crystal particles contained in the dispersed nano-particle ink to be suppressed,

a wiring pattern of the sensor is traced on the surface of the undercoat film of the substrate surface using the dispersed nano-particle ink, with the dispersed nano-particle ink being baked and metalized.

The 2nd invention according to the 1st invention is characterized in that

the substrate is silicon wafer or GaAs or GaP or any metal from Al, Cu, Fe, Ti and SUS or carbon.

The 3rd invention is characterized in

a sensor-fitted substrate having a sensor over a substrate for measuring a temperature or/and strain of the substrate in a high-temperature process, wherein

the sensor measures a resistance value of a metal serving as a resistor which is converted into a temperature, thereby measuring the temperature or/and strain of the substrate,

the substrate is a substrate where metals are not diffused, the metals being contained in a dispersed nano-particle ink of nano-particles of any metal among Au, Ag, Pt, Ni and Cu or alloy nano-particles containing Pd or Cu or Si in Ag or a dispersed nano-particle ink in which Ag nano-particles and nano-particles of Pd or Cu or Si are mixed, and wherein

a wiring pattern of the sensor is traced on the surface of the substrate, by coating directly with the dispersed nano-particle ink, with the dispersed nano-particle ink being baked and metalized.

The 4th invention according to the 3rd invention is characterized in that

the substrate is glass or quartz glass or sapphire or ceramic or polyimide or Teflon or epoxy or a fiber reinforced material of these plastics.

The 5th invention is characterized in

a sensor-fitted substrate having a sensor over a substrate for measuring a temperature or/and strain of the substrate in a high-temperature process, wherein

the sensor measures a resistance value of the metal serving as a resistor which is converted into a temperature or/and strain, thereby measuring the temperature or/and strain of the substrate,

a wiring pattern of the sensor is traced on the surface of the substrate by coating with a dispersed nano-particle ink of nano-particles of any metal among Au, Ag, Pt, Ni and Cu or alloy nano-particles containing Pd or Cu or Si in Ag or a dispersed nano-particle ink in which Ag nano-particles and nano-particles of Pd or Cu or Si are mixed, with the dispersed nano-particle ink being baked an metalized, and wherein

the substrate with the wiring pattern of the sensor traced and metalized thereon is treated by annealing at least a temperature employed at the time of the high-temperature process, or, while flowing a current in the wiring pattern of the sensor.

The 6th invention according to the 1st invention or the 2nd invention in characterized in that

the substrate with the wiring pattern of the sensor traced and metalized thereon is treated by annealing at least a temperature employed at the time of the high-temperature process, or, while flowing a current in the wiring pattern of the sensor.

The 7th invention according to the 3rd invention or the 4th invention is characterized in that

the substrate with the wiring pattern of the sensor traced and metalized thereon is treated by annealing at least a temperature employed at the time of the high-temperature process, or, while flowing a current in the wiring pattern of the sensor.

The 8th invention is characterized in

a sensor-fitted substrate having a sensor over a substrate for measuring a temperature or/and strain of the substrate in a high-temperature process, wherein

the sensor measures a resistance value of a metal serving as a resistor which is converted into a temperature or/and strain, thereby measuring the temperature or/and strain of the substrate,

a wiring pattern of the sensor is traced on the surface of the substrate by coating with a dispersed nano-particle ink of nano-particles of any metal among Au, Ag, Pt, Ni and Cu or alloy nano-particles containing Pd or Cu or Si in Ag or a dispersed nano-particle ink in which Ag nano-particles and nano-particles of Pd or Cu or Si are mixed, with the dispersed nano-particle ink being baked and metalized, and

an overcoat-treatment is performed on the surface of the substrate with the wiring pattern of the sensor traced and metalized thereon, the treatment being employed, compared to when no overcoat-treatment is performed on this substrate surface, to allow growth of metal crystal particles contained in the dispersed nano-particle ink to be suppressed, the warping of the substrate to be reduced, and to induce the substrate to become less prone to the influence of air convection, and moreover to allow tearing of the wiring pattern of the sensor to be suppressed.

The 9th invention according to the 1st invention or the 2nd invention is characterized in that

an overcoat-treatment is performed on the surface of the substrate with the wiring pattern of the sensor traced and metalized thereon, the treatment being employed, compared to when no overcoat-treatment is performed on this substrate surface, to allow growth of metal crystal particles contained in the dispersed nano-particle ink to be suppressed, warping of the substrate to be reduced, and to induce the substrate to become less prone to the influence of air convection, and moreover allow tearing of the wiring pattern of the sensor to be suppressed.

The 10th invention according to the 3rd invention or the 4th invention is characterized in

an overcoat-treatment is performed on the surface of the substrate with the wiring pattern of the sensor traced and metalized thereon, the treatment being employed, compared to when no overcoat-treatment is performed on this substrate surface, to allow growth of metal crystal particles contained in the dispersed nano-particle ink to be suppressed, warping of the substrate to be reduced, and to induce the substrate to become less prone to the influence of air convection, and moreover allow tearing of the wiring pattern of the sensor to be suppressed.

The 11th invention according to the 5th invention is characterized in that

an overcoat-treatment is performed on the surface of the substrate with the wiring pattern of the sensor traced and metalized thereon and treated by annealing, the treatment being employed, compared to when no overcoat-treatment is performed on this substrate surface, to allow growth of metal crystal particles contained in the dispersed nano-particle ink to be suppressed, warping of the substrate to be reduced, and to induce the substrate to become less prone to the influence of air convection, and moreover to allow tearing of the wiring pattern of the sensor to be suppressed.

The 12th invention according to the 6th invention is characterized in that

an overcoat-treatment is performed on the surface of the substrate with the wiring pattern of the sensor traced and metalized thereon and treated by annealing, the treatment being employed, compared to when no overcoat-treatment has been performed on this substrate surface, to allow growth of metal crystal particles contained in the dispersed nano-particle ink to be suppressed, warping of the substrate to be reduced, and to induce the substrate to become less prone to the influence of air convection, and moreover to allow tearing of the wiring pattern of the sensor to be suppressed.

The 13th invention according to the 7th invention is characterized in that

an overcoat-treatment is performed on the surface of the substrate with the wiring pattern of the sensor traced and metalized thereon and treated by annealing, the treatment being employed, compared to when no overcoat-treatment is performed on this substrate surface, to allow growth of metal crystal particles contained in the dispersed nano-particle ink to be suppressed, warping of the substrate to be reduced, and to induce the substrate to become less prone to the influence of air convection, and moreover to allow tearing of the wiring pattern of the sensor to be suppressed.

The 14th invention is characterized in

a sensor-fitted substrate having a sensor over a substrate for measuring a temperature or/and strain of the substrate in a high-temperature process, wherein

the sensor measures a resistance value of a metal serving as a resistor which is converted into a temperature or/and strain, thereby measuring the temperature or/and strain of the substrate,

a wiring pattern of the sensor is traced on the surface of the substrate by coating with a dispersed nano-particle ink of nano-particles of any metal among Au, Ag, Pt, Ni and Cu or alloy nano-particles containing Pd or Cu or Si in Ag or a dispersed nano-particle ink in which Ag nano-particles and nano-particles of Pd or Cu or Si are mixed, with the dispersed nano-particle ink being baked and metalized,

an overcoat-treatment is performed on the surface of the substrate with the wiring pattern of the sensor traced and metalized thereon, the treatment being employed, compared to when no overcoat-treatment is performed on this substrate surface, to allow growth of metal crystal particles contained in the dispersed nano-particle ink to be suppressed, warping of the substrate to be reduced, and to induce the substrate to become less prone to the influence of air convection, and moreover to allow tearing of

the wiring pattern of the sensor to be suppressed, and the overcoat-treated substrate is treated by annealing at least a temperature employed at the time of the high-temperature process, or, while flowing a current in the wiring pattern of the sensor.

The 15th invention comprises the 9th invention in which

the overcoat-treated substrate is treated by annealing at least a temperature employed at the time of the high-temperature process, or, while flowing a current in the wiring pattern of the sensor.

The 16th invention according to the 10th invention is characterized in that

the overcoat-treated substrate is treated by annealing at least a temperature employed at the time of the high-temperature process, or, while flowing a current in the wiring pattern of the sensor.

The 17th invention according to the 11th invention is characterized in that

the overcoat-treated substrate is treated by annealing at least a temperature employed at the time of the high-temperature process, or, while flowing a current in the wiring pattern of the sensor.

The 18th invention according to the 12th invention is characterized in that

the overcoat-treated substrate is treated by annealing at least a temperature employed at the time of the high-temperature process, or, while flowing a current in the wiring pattern of the sensor.

The 19th invention according to the 13th invention is characterized in that

the overcoat-treated substrate is treated by annealing at least a temperature employed at the time of the high-temperature process, or, while flowing a current in the wiring pattern of the sensor.

The 20th invention is characterized in

a method for producing a sensor-fitted substrate having a sensor over a substrate for measuring a temperature or/and strain of the substrate in a high-temperature process, wherein

the sensor measures a resistance value of a metal serving as a resistor which is converted into a temperature or/and strain, thereby measuring the temperature or/and strain of the substrate, and

the substrate is a substrate where metals are diffused, the metals being contained in a dispersed nano-particle ink of nano-particles of any metal among Au, Ag, Pt, Ni and Cu or alloy nano-particles containing Pd or Cu or Si in Ag or a dispersed nano-particle ink in which Ag nano-particles and nano-particles of Pd or Cu or Si are mixed,

the method comprising:

a step of forming an undercoat film on the surface of the substrate, the film being configured, compared to when no undercoat film is formed, to allow a strength of close contact of the dispersed nano-particle ink with the substrate to be increased, diffusion of the dispersed nano-particle ink into the substrate to be suppressed, and growth of metal crystal particles contained in the dispersed nano-particle ink to be suppressed;

a step of forming a wiring pattern of the sensor on the surface of the undercoat film of the substrate surface by using the dispersed nano-particle ink; and

a step of firing and metalizing the dispersed nano-particle ink.

The 21st invention is characterized in

a method for producing a sensor-fitted substrate having a sensor over a substrate for measuring a temperature or/and strain of the substrate in a high-temperature process, wherein

the sensor measures a resistance value of a metal serving as a resistor which is converted into a temperature or/and strain, thereby measuring the temperature or/and strain of the substrate, and

the substrate is a substrate where metals are not diffused, the metals being contained in a dispersed nano-particle ink of nano-particles of any metal among Au, Ag, Pt, Ni and Cu or alloy nano-particles containing Pd or Cu or Si in Ag or a dispersed nano-particle ink in which Ag nano-particles and nano-particles of Pd or Cu or Si are mixed,

the method comprising:

a step of forming a wiring pattern of the sensor by coating directly with the dispersed nano-particle ink; and

a step of firing and metalizing the dispersed nano-particle ink.

The 22nd invention is characterized in

a method for producing a sensor-fitted substrate having a sensor over a substrate for measuring a temperature or/and strain of the substrate in a high-temperature process, wherein

the sensor measures a resistance value of a metal serving as a resistor which is converted into a temperature or/and strain, thereby measuring the temperature or/and strain of the substrate, and

the substrate is a substrate where metals are diffused, the metals being contained in a dispersed nano-particle ink of nano-particles of any metal among Au, Ag, Pt, Ni and Cu or alloy nano-particles containing Pd or Cu or Si in Ag or a dispersed nano-particle ink in which Ag nano-particles and nano-particles of Pd or Cu or Si are mixed,

the method comprising:

a step of forming an undercoat film on the surface of the substrate, the film being configured, compared to when no undercoat film is formed, to allow a strength of close contact of the dispersed nano-particle ink with the substrate to be increased, diffusion of the dispersed nano-particle ink into the substrate to be suppressed, and growth of metal crystal particles contained in the dispersed nano-particle ink to be suppressed;

a step of forming a wiring pattern of the sensor on the surface of the undercoat film of the substrate surface by using the dispersed nano-particle ink;

a step of firing and metalizing the dispersed nano-particle ink, and

the step of treating by annealing the substrate with the wiring pattern of the sensor traced and metalized thereon at least a temperature employed at the time of the high-temperature process, or, while flowing a current in the wiring pattern of the sensor.

The 23rd invention is characterized in

a method for producing a sensor-fitted substrate having a sensor over a substrate for measuring a temperature or/and strain of the substrate in a high-temperature process, wherein

the sensor measures a resistance value of a metal serving as a resistor which is converted into a temperature or/and strain, thereby measuring the temperature or/and strain of the substrate, and

the substrate is a substrate where metals are not diffused, the metals being contained in a dispersed nano-particle ink of nano-particles of any metal among Au, Ag, Pt, Ni and Cu or alloy nano-particles containing Pd or Cu or Si in Ag or a dispersed nano-particle ink in which Ag nano-particles and nano-particles of Pd or Cu or Si are mixed,

the method comprising:

a step of forming a wiring pattern of the sensor by coating directly with the dispersed nano-particle ink;

a step of firing and metalizing the dispersed nano-particle ink; and

a step of treating by annealing the substrate with the wiring pattern of the sensor traced and metalized thereon at least a temperature employed at the time of the high-temperature process, or, while flowing a current in the wiring pattern of the sensor.

The 24th invention is characterized in

a method for producing a sensor-fitted substrate having a sensor over a substrate for measuring a temperature or/and strain of the substrate in a high-temperature process, wherein

the sensor measures a resistance value of a metal serving as a resistor which is converted into a temperature or/and strain, thereby measuring the temperature or/and strain of the substrate, and

the substrate is a substrate where metals are diffused, the metals being contained in a dispersed nano-particle ink of nano-particles of any metal among Au, Ag, Pt, Ni and Cu or alloy nano-particles containing Pd or Cu or Si in Ag or a dispersed nano-particle ink in which Ag nano-particles and nano-particles of Pd or Cu or Si are mixed,

the method comprising:

a step of forming an undercoat film on the surface of the substrate, the film being configured, compared to when no undercoat film has been formed, to allow a strength of close contact of the dispersed nano-particle ink with the substrate to be increased, diffusion of the dispersed nano-particle ink into the substrate to be suppressed, and growth of metal crystal particles contained in the dispersed nano-particle ink to be suppressed;

a step of forming a wiring pattern of the sensor on the surface of the undercoat film of the substrate surface by using the dispersed nano-particle ink;

a step of firing and metalizing the dispersed nano-particle ink;

a step of treating by annealing the substrate with the wiring pattern of the sensor traced and metalized thereon at least a temperature employed at the time of the high-temperature process, or, while flowing a current in the wiring pattern of the sensor; and

a step of performing an overcoat-treatment on the surface of the substrate with the wiring pattern of the sensor traced and metalized thereon and treated by annealing, the treatment being employed, compared to when no overcoat-treatment is performed on this substrate surface, to allow growth of metal crystal particles contained in the dispersed nano-particle ink to be suppressed, warping of the substrate to be reduced, and to induce the substrate to become less prone to the influence of air convection, and moreover to allow tearing of the wiring pattern of the sensor to be suppressed.

The 25th invention is characterized in

a method for producing a sensor-fitted substrate having a sensor over a substrate for measuring a temperature or/and strain of the substrate in a high-temperature process, wherein

the sensor measures a resistance value of a metal serving as a resistor which is converted into a temperature or/and strain, thereby measuring the temperature or/and strain of the substrate, and

the substrate is a substrate where metals are not diffused, the metals being contained in a dispersed nano-particle ink of nano-particles of any metal among Au, Ag, Pt, Ni and Cu or alloy nano-particles containing Pd or Cu or Si in Ag or a dispersed nano-particle ink in which Ag nano-particles and nano-particles of Pd or Cu or Si are mixed,

the method comprising:

a step of forming on the surface of the substrate a wiring pattern of the sensor by coating directly with the dispersed nano-particle ink;

a step of firing and metalizing the dispersed nano-particle ink;

a step of treating by annealing the substrate with the wiring pattern of the sensor traced and metalized thereon at least a temperature employed at the time of the high-temperature process, or, while flowing a current in the wiring pattern of the sensor; and

a step of performing an overcoat-treatment on the surface of the substrate with the wiring pattern of the sensor traced and metalized thereon and treated by annealing, the treatment being employed, compared to when no overcoat-treatment is performed on this substrate surface, to allow growth of metal crystal particles contained in the dispersed nano-particle ink to be suppressed, warping of the substrate to be reduced, and to induce the substrate to become less prone to the influence of air convection, and moreover to allow tearing of the wiring pattern of the sensor to be suppressed.

The 26th invention is characterized in

a method for producing a sensor-fitted substrate having a sensor over a substrate for measuring a temperature or/and strain of the substrate in a high-temperature process, wherein

the sensor measures a resistance value of a metal serving as a resistor which is converted into a temperature or/and strain, thereby measuring the temperature or/and strain of the substrate, and

the substrate is a substrate where metals are diffused, the metals being contained in a dispersed nano-particle ink of nano-particles of any metal among Au, Ag, Pt, Ni and Cu or alloy nano-particles containing Pd or Cu or Si in Ag or a dispersed nano-particle ink in which Ag nano-particles and nano-particles of Pd or Cu or Si are mixed,

the method comprising:

a step of forming an undercoat film on the surface of the substrate, the film being configured, compared to when no undercoat film is formed, to allow a strength of close contact of the dispersed nano-particle ink with the substrate to be increased, diffusion of the dispersed nano-particle ink into the substrate to be suppressed, and growth of metal crystal particles contained in the dispersed nano-particle ink to be suppressed;

a step of forming a wiring pattern of the sensor on the surface of the undercoat film of the substrate surface by using the dispersed nano-particle ink;

a step of firing and metalizing the dispersed nano-particle ink;

a step of performing an overcoat-treatment on the surface of the substrate with the wiring pattern of the sensor traced and metalized thereon, the treatment being employed, compared to when no overcoat-treatment is performed on this substrate surface, to allow growth of metal crystal particles contained in the dispersed nano-particle ink to be suppressed, warping of the substrate to be reduced, and to induce the substrate to become less prone to the influence of air convection, and moreover to allow tearing of the wiring pattern of the sensor to be suppressed; and

a step of treating by annealing the overcoat-treated substrate at least a temperature employed at the time of the high-temperature process, or, while flowing a current in the wiring pattern of the sensor.

The 27th invention is characterized in

a method for producing a sensor-fitted substrate having a sensor over a substrate for measuring a temperature or/and strain of the substrate in a high-temperature process, wherein

the sensor measures a resistance value of a metal serving as a resistor which is converted into a temperature or/and strain, thereby measuring the temperature or/and strain of the substrate, and

the substrate is a substrate where metals are diffused, the metals being contained in a dispersed nano-particle ink of nano-particles of any metal among Au, Ag, Pt, Ni and Cu or alloy nano-particles containing Pd or Cu or Si in Ag or a dispersed nano-particle ink in which Ag nano-particles and nano-particles of Pd or Cu or Si are mixed,

the method comprising:

a step of forming a wiring pattern of the sensor by coating directly with the dispersed nano-particle ink;

a step of firing and metalizing the dispersed nano-particle ink;

a step of performing an overcoat-treatment on the surface of the substrate with the wiring pattern of the sensor traced and metalized thereon, the treatment being employed, compared to when no overcoat-treatment is performed on this substrate surface, to allow growth of metal crystal particles contained in the dispersed nano-particle ink to be suppressed, warping of the substrate to be reduced, and to induce the substrate to become less prone to the influence of air convection, and moreover to allow tearing of the wiring pattern of the sensor to be suppressed; and

a step of treating by annealing the overcoat-treated substrate at least a temperature employed at the time of the high-temperature process, or, while flowing a current in the wiring pattern of the sensor.

The 28th invention is characterized in

a method for producing a sensor-fitted substrate having a sensor over a substrate for measuring a temperature or/and strain of the substrate in a high-temperature process, wherein

the sensor measures a resistance value of a metal serving as a resistor which is converted into a temperature or/and strain, thereby measuring the temperature or/and strain of the substrate, and

the substrate is a substrate where metals are diffused, the metals being contained in a dispersed nano-particle ink of nano-particles of any metal among Au, Ag, Pt, Ni and Cu or alloy nano-particles containing Pd or Cu or Si in Ag or a dispersed nano-particle ink in which Ag nano-particles and nano-particles of Pd or Cu or Si are mixed,

the method comprising:

a step of forming an undercoat film on the surface of the substrate, the film being configured, compared to when no undercoat film is formed, to allow a strength of close contact of the dispersed nano-particle ink with the substrate to be increased, diffusion of the dispersed nano-particle ink into the substrate to be suppressed, and growth of metal crystal particles contained in the dispersed nano-particle ink to be suppressed;

a step of forming a wiring pattern of the sensor on the surface of the undercoat film of the substrate surface by using the dispersed nano-particle ink;

a step of firing and metalizing the dispersed nano-particle ink;

a step of treating by annealing the substrate with the wiring pattern of the sensor traced and metalized thereon at least a temperature employed at the time of the high-temperature process, or, while flowing a current in the wiring pattern of the sensor; and

a step of performing an overcoat-treatment on the surface of the substrate with the wiring pattern of the sensor traced and metalized thereon and treated by annealing, the treatment being employed, compared to when no overcoat-treatment is performed on this substrate surface, to allow growth of metal crystal particles contained in the dispersed nano-particle ink to be suppressed, warping of the substrate to be reduced, and to induce the substrate to become less prone to the influence of air convection, and moreover to allow tearing of the wiring pattern of the sensor to be suppressed; and

a step of treating by annealing the overcoat-treated substrate at least a temperature employed at the time of the high-temperature process, or, while flowing a current in the wiring pattern of the sensor.

The 29th invention is characterized in

a method for producing a sensor-fitted substrate having a sensor over a substrate for measuring a temperature or/and strain of the substrate in a high-temperature process, wherein

the sensor measures a resistance value of a metal serving as a resistor which is converted into a temperature or/and strain, thereby measuring the temperature or/and strain of the substrate, and

the substrate is a substrate where metals are not diffused, the metals being contained in a dispersed nano-particle ink of nano-particles of any metal among Au, Ag, Pt, Ni and Cu or alloy nano-particles containing Pd or Cu or Si in Ag or a dispersed nano-particle ink in which Ag nano-particles and nano-particles of Pd or Cu or Si are mixed,

the method comprising:

a step of forming on the surface of the substrate a wiring pattern of the sensor by coating directly with the dispersed nano-particle ink;

a step of firing and metalizing the dispersed nano-particle ink;

a step of treating by annealing the substrate with the wiring pattern of the sensor traced and metalized thereon at least a temperature employed at the time of the high-temperature process, or, while flowing a current in the wiring pattern of the sensor;

a step of performing an overcoat-treatment on the surface of the substrate with the wiring pattern of the sensor traced and metalized thereon and treated by annealing, the treatment being employed, compared to when no overcoat-treatment is performed on this substrate surface, to allow growth of metal crystal particles contained in the dispersed nano-particle ink to be suppressed, warping of the substrate to be reduced, and to induce the substrate to become less prone to the influence of air convection, and moreover to allow tearing of the wiring pattern of the sensor to be suppressed; and

a step of treating by annealing the overcoat-treated substrate at least a temperature employed at the time of the high-temperature process, or, while flowing a current in the wiring pattern of the sensor.

### Effects of the Invention

The sensor-fitted substrate of the present invention is produced by tracing a wiring pattern of the sensor over a substrate using a dispersed nano-particle ink of nano-particles of any metal among Au, Ag, Pt, Ni and Cu or alloy nano-particles containing Pd or Cu or Si in Ag or a dispersed nano-particle ink in which Ag nano-particles and nano-particles of Pd or Cu or Si are mixed, and the dispersed nano-particle ink being baked and metalized.

Here, the dispersed nano-particle ink is one in which particles of few hundred nm or less are dispersed in a solvent, and the dispersed nano-particle ink is used to trace a wiring pattern of the sensor and then baked. By performing baking, the organic dispersants and solvents contained in the dispersed nano-particle ink are evaporated, the nano-particles melt into each other and fuse together to acquire electric conductivity, metalizing into a stable shape. When a wiring pattern of the sensor is produced in this way, owing to the extremely large presence of grain boundaries of metal crystals, the apparent rate of electric resistance, or the like, becomes large even when the same metal is used. Due to this, the noise becomes relatively small, allowing a fine variation in the temperature or strain to be measured with good accuracy. Thus, a sensor, such as a resistance thermometer or a strain gauge, measuring the resistance value of a metal which is converted into temperature or/and strain to measure the temperature or/and strain of the substrate, becomes less prone to the influence of noise or the like, which improves the precision of the measurements. In addition, by having a larger resistance value, the meander wiring unit can be reduced, allowing for measurements of temperature or/and strain in finer areas.

It was revealed by the present inventors that substrates such as silicon wafers had the problem that when tracing and metalizing by coating directly with a dispersed nano-particle ink, metals contained in the dispersed nano-particle ink diffused into the substrate. In addition, it was revealed that the strength of close contact of the dispersed nano-particle ink with the substrate was low. In addition, it was revealed that the resistance value did not stabilize when constitution has been performed as a sensor-fitted substrate. In addition, it was revealed that the warping of the substrate occurred.

Thus, an undercoat film is formed on the substrate surface, then, a wiring pattern of the sensor is traced and metalized using a dispersed nano-particle ink. This elevates the strength of close contact of the dispersed nano-particle ink with the substrate compared to when no undercoat film has been formed on the substrate surface. In addition, the diffusion into the substrate is suppressed in a similar manner. In addition, the growth of metal crystal particles is suppressed in a similar manner, which stabilizes the resistance value when constitution has been performed as a sensor-fitted substrate (the 1st invention, the 2nd invention, the 9th invention, the 12th invention, the 15th invention, the 18th invention, the 20th invention, the 22nd invention, the 24th invention, the 26th invention and the 28th invention).

In contrast, with substrates such as glass, even if tracing and metallization were performed by coating directly with a dispersed nano-particle ink, no metal diffuses into the substrate. Thus, regarding such substrates, a wiring pattern of the sensor may be traced and metalized by coating directly on the surface of the substrate with a dispersed nano-particle ink (the 3rd invention, the 4th invention, the 7th invention, the 10th invention, the 13th invention, the 16th invention, the 19th invention, the 21st invention, the 23rd invention, the 25th invention, the 27th invention and the 29th invention).

In the 5th invention, the 6th invention, the 7th invention, the 11th invention, the 12th invention, the 13th invention, the 17th invention, the 18th invention, the 19th invention, the 22nd invention, the 23rd invention, the 24th invention, the 25th invention, the 28th invention and the 29th invention, the substrate with the wiring pattern of the sensor traced and metalized thereon is treated by annealing at least a temperature employed at the time of the high-temperature process, or, while flowing a current in the wiring pattern of the sensor.

That is to say, the annealing treatment promotes the growth of metal crystal particles, and in addition, stabilizes unstable atoms present at the crystal boundary, causing the particle growth to reach an equilibrium state. This stabilizes the boundary energy, stabilizing the electric resistance value at the operating temperature when a sensor-fitted substrate has been constituted. Thus, a stable sensor-fitted substrate can be produced, in which a variation in the resistance value over time during the use of the sensor-fitted substrate is not likely to occur.

In the 8th invention, the 9th invention, the 10th invention, the 11th invention, the 12th invention, the 13th invention, the 14th invention, the 15th invention, the 16th invention, the 17th invention, the 18th invention, the 19th invention, the 24th invention, the 25th invention, the 26th invention, the 27th invention, the 28th invention and the 29th invention, an overcoat-treatment is performed on the surface of the substrate where a wiring pattern of the sensor has been traced and metalized. This suppresses the growth of metal crystal particles compared to when no overcoat-treatment has been performed on the substrate surface, stabilizing the electric resistance value when a sensor-fitted substrate has been constituted. Furthermore, warping of the substrate can be reduced in a similar manner. In addition, having become less prone to the influence of air convection in a similar manner, tearing of the wiring pattern of the sensor can be suppressed.

In the 14th invention, the 15th invention, the 16th invention, the 17th invention, the 18th invention, the 19th invention, the 26th invention, the 27th invention, the 28th invention and the 29th invention, the overcoat-treated substrate is treated by annealing at least a temperature employed at the time of the high-temperature process, or, while flowing a current in the wiring pattern of the sensor. With this, compared to when no treatment by annealing has been performed on the overcoat-treated substrate, since a treatment by annealing is carried out after the overcoat-treatment, the overcoating material can be stabilized and the resistance value becomes stable when constitution has been performed as a sensor-fitted substrate.

In particular, in the 17th invention, the 18th invention, the 19th invention, the 28th invention and the 29th invention, a treatment by annealing is carried out prior to overcoat-treatment and a further treatment by annealing is carried out after the overcoat-treatment. With a treatment by annealing carried out prior to overcoat-treatment, compared to treatment by annealing carried out after the overcoat-treatment, the line width of the wiring pattern is prone to becoming non-uniform due to movements of crystal particles, leading to a state in which the electric resistance value varies. Thus, by carrying out the treatment by annealing after the overcoat-treatment, the movements of crystal particles are suppressed, the line width of the wiring pattern becomes uniform, and the electric resistance value stabilizes without varying.

In addition, by carrying out the treatment by annealing after the overcoat-treatment, the time needed for the treatment by annealing prior to the overcoat-treatment can be shortened.

### BEST MODE FOR CARRYING OUT THE INVENTION

Hereafter, embodiments of the sensor-fitted substrate and the method for producing the sensor-fitted substrate according to the present invention will be described by referring to figures. Note that, silicon wafers are assumed as substrates to provide the descriptions below. However, in addition to silicon wafers, the present invention can be applied to substrates, such as glass substrates, which require that the temperature or/and the strain of the substrate in a high-temperature process be measured during production of the substrate. Now, herein, a high-temperature process is a process which may reach a temperature of approximately 250° C. or higher.

As far as the type of substrate, adequate is either a substrate where metals contained in a dispersed nano-particle ink diffuse into or a substrate where metals contained in a dispersed nano-particle ink do not diffuse into.

As substrates where metals contained in a dispersed nano-particle ink diffuse into, concretely, are silicon wafer or GaAs or GaP or any metal from Al, Cu, Fe, Ti and SUS or carbon.

As substrates where metals contained in a dispersed nano-particle ink do not diffuse into, concretely, are glass or quartz glass or sapphire or ceramic or polyimide or Teflon or epoxy or fiber reinforced materials of these plastics.

In addition, dispersed nano-particle ink, herein, is used with the meaning of an ink comprising nano-particles of any metal among Au, Ag, Pt, Ni and Cu or alloy nano-particles containing Pd or Cu or Si in Ag with a particle size of few hundred nm or less or a dispersed nano-particle ink in which Ag nano-particles and nano-particles of Pd or Cu or Si are mixed, uniformly dispersed in a solvent.

FIGS. 1A, 1B, 1C and 1D show cross sections of a sensor-fitted silicon wafer 100 at each production step in the examples. Descriptions will be provided below along with reverences to the figures.

First, a silicon wafer 10 identical to the an silicon wafer used in the production of a semiconductor device is prepared, undercoat film application (primer coat) is performed over this silicon wafer 10 for such purpose as raising the degree of close contact of the dispersed nano-particle ink onto the silicon wafer 10.

The silicon wafer 10 was found to have the problem that, if traced and metalized by coating directly with a dispersed nano-particle ink, metals contained in the dispersed nano-particle ink diffuse into the substrate. In addition the strength of close contact of the dispersed nano-particle ink with the substrate was found to be low. In addition, the resistance value was found not to become stable when constitution has been performed as a sensor-fitted silicon wafer 100. In addition, a warping of silicon wafer 10 was found to occur. Consequently, an undercoat film 11 is formed on the surface of the silicon wafer 10 which, compared to when no undercoat film has been formed on this silicon wafer surface, allows the strength of close contact of the dispersed nano-particle ink with the substrate to be increased, the diffusion of the dispersed nano-particle ink into the silicon wafer 10 to be suppressed, and the growth of metal crystal particles contained in the dispersed nano-particle ink to be suppressed. As materials for undercoat films allowing such problems to be solved, organic materials such as polyimide, inorganic materials such as Ni, Cr, Ti, Al2O3, MN and SiO2, and hybrid materials in which these organic materials and inorganic materials are mixed may be cited.

In addition, methods of treating the undercoat film 11 include sputter, ion plating, vapor deposition, spin-coat, dipping, screen printing, thermal fusion bonding and the combination of silane coupling and Ni plating.

Sputter, ion plating and vapor deposition are applied in treatment of the undercoat film 11 using organic materials and inorganic materials.

Spin-coat, dipping, screen printing and thermal fusion bonding are applied in treating the undercoat film 11 using organic materials and hybrid materials.

For example, with materials comprising mixed organic materials and inorganic materials serving as a spin-coating material (raw material solution), this spin-coating material is placed on top of a silicon wafer 10 and spun, generating an undercoat film 11 comprising raw materials uniformly dispersed by the spin-coat method. The undercoat film 11 is fixed onto the silicon wafer 10 by carrying out a drying treatment at 150° C. to 200° C. for approximately one hour. Here, among the materials comprising mixed organic materials and inorganic materials, materials that allow the degree of close contact to be raised after the dispersed nano-particle ink membrane is baked are used for the organic materials. In addition, among the materials comprising mixed organic materials and inorganic materials, materials that allow the heat resistance at the time of high-temperature process to be raised, such as, Ni, Cr, Ti, Al2O3, AlN and SiO2, are used for the inorganic materials (FIG. 1A).

The above assumes the case of a substrate such as silicon wafer 10, in which metals contained in the dispersed nano-particle ink diffuse into the substrate. In contrast, for a substrate such as glass, metals contained in the dispersed nano-particle ink does not diffuse into the substrate even if tracing was performed by coating directly with the dispersed nano-particle ink. Thus, regarding such a substrate, the wiring pattern of the sensor may be traced and metalized by coating directly with the dispersed nano-particle ink on the surface of the substrate without performing the undercoat film 11.

Next, for the purpose of refining the wiring pitch, a liquid-repellent 12 is coated over the undercoat film 11 in order to increase water-repelling properties of the dispersed nano-particle ink towards silicon wafer 10. Coating of the liquid-repellent 12 can be carried out by the spin-coat method. A fluorine series polymer solution or the like can be used as the liquid-repellent 12 (FIG. 1B).

Next, the wafer 10 is heated at a predetermined temperature to subject the liquid-repellent 12 to a drying treatment. This leaves on the order of one molecular layer of liquid-repellent 12 above the undercoat film 11, prevents the ink hitting during ink jet printing from spreading, and allows for printing with fine lines. Since this liquid-repellent layer is evaporated in the baking process of the dispersed nano-particle ink film, it has no effects on the dispersed nano-particle ink membrane coming into close contact on the silicon wafer 10 surface.

Next, over the undercoat film 11 of the silicon wafer 10, a dispersed nano-particle ink containing Ag as nano-particles is traced into the shape pattern of a temperature sensor or a strain sensor 1 being created, and then baked. By performing baking, the organic dispersants and solvents contained in the dispersed nano-particle ink are evaporated, the nano-particles melt into each other and fuse together to acquire electric conductivity, metalizing into a stable shape.

The sensor 1 in the present example is a sensor that measures the temperature or/and strain of the silicon wafer 1 by measuring the resistance value of Ag. For example, dispersed nano-particle ink is traced into the shapes of a sensor portion and a wiring portion that is electrically connected to the sensor portion by the ink jet method. Any methods other than the ink jet method are adequate, for example, the gravure printing method can be used. In addition, as far as metal nano-particles contained in the dispersed nano-particle ink, nano-particles of any metal among Au, Pt, Ni and Cu may be used alternatively to Ag. In addition, alloy nano-particles containing Pd or Cu or Si in Ag are also adequate. In addition, Ag nano-particles and nano-particles of Pd or Cu or Si may be mixed (FIG. 1C).

Next, the silicon wafer 10 with the wiring pattern of the sensor 1 traced and metalized thereon is treated by annealing at least a temperature employed at the time of the high-temperature process, or, while flowing a current in the wiring pattern of the sensor 1. For example, annealing is carried out at a temperature that is higher than the maximum temperature for actual use.

The annealing treatment promotes the growth of metal crystal particles and stabilizes unstable atoms present at the crystal boundary, causing the particle growth to reach an equilibrium state. This stabilizes the boundary energy, stabilizing the electric resistance value at the operating temperature of the sensor-fitted silicon wafer 100 when the sensor-fitted silicon wafer 100 has been constituted.

Next, an overcoat-treatment is performed on the surface of silicon wafer 10 with the wiring pattern of sensor 1 traced and metalized thereon, which, compared to when no overcoat-treatment has been performed on the silicon wafer surface, allows the growth of metal crystal particles contained in the dispersed nano-particle ink to be suppressed, the warping of the silicon wafer 10 to be reduced, and, having become less prone to the influence of air convection, allows the tearing of the wiring pattern of the sensor 1 to be suppressed. As overcoating material 13 that fulfill such required specs, organic materials such as polyimide, inorganic materials such as Al2O3, AlN and SiO2, and hybrid materials in which these organic materials and inorganic materials are mixed may be cited.

In addition, as treatment methods for the overcoat, sputter, ion plating, vapor deposition, spin-coat, dipping, screen printing, thermal fusion bonding, and Al plating followed by alumite treatment may be cited.

Sputter, ion plating and vapor deposition are applied when overcoat-treatment is carried out using organic materials and inorganic materials.

Spin-coat, dipping, screen printing, and thermal fusion bonding are applied when overcoat-treatment is carried out using organic materials and hybrid materials.

By suppressing the growth of metal crystal particles contained in the dispersed nano-particle ink, the electric resistance value of sensor 1 becomes stable. In addition, by performing overcoat-treatment, generation of impurities, such as Ag becoming sulfurated, is suppressed. In addition, by performing overcoat-treatment, the internal stress is alleviated, allowing the warping of the wiring pattern of the sensor 1 to be reduced (FIG. 1D).

Next, overcoat-treated sensor-fitted silicon wafer 100 is treated by annealing at at least a temperature employed at the time of the high-temperature process, or, by flowing a current in the wiring pattern of the sensor 1.

With this, compared to when no treatment by annealing has been performed on the overcoat-treated sensor-fitted silicon wafer 100, since a treatment by annealing is carried out after the overcoat-treatment, overcoating material 13 can be stabilized and the resistance value becomes stable when constitution has been performed as a sensor-fitted silicon wafer 100.

Here, with a treatment by annealing carried out prior to overcoat-treatment, compared to treatment by annealing carried out after the overcoat-treatment, the line width of the wiring pattern is prone to becoming non-uniform due to movements of crystal particles, leading to a state in which the electric resistance value varies. By carrying out the treatment by annealing after the overcoat-treatment, the movements of crystal particles are suppressed, the line width of the wiring pattern becomes uniform, and the electric resistance value stabilizes without varying.

In addition, by carrying out the treatment by annealing after the overcoat-treatment, the time needed for the treatment by annealing prior to the overcoat-treatment can be shortened.

The sensor-fitted wafer 100 is produced as described above.

However, the following steps are added suitably according to the product needs.

For example, with a ribbon cable being attached to the wiring pattern on the substrate in order to perform input/output of the electrical output, an electrical input/output terminal on the substrate is attached to the electrical input/output terminal on the ribbon cable side with an anisotropic electric conductive adhesive sheet. In this case, an anisotropic electric conductive sheet of the via filling type, in which metals are embedded in open holes in a film, is used for the anisotropic electric conductive adhesive sheet.

According to the present embodiment, the following effects are obtained:

A) When a wiring pattern of the sensor 1 is produced using a dispersed nano-particle ink, owing to the extremely large presence of grain boundaries of metal crystals, the apparent rate of electric resistance becomes large even when the same metal is used. Due to this, the noise becomes relatively small, allowing a fine variation in the temperature or strain to be measured with good accuracy. Thus, a sensor, such as a resistance thermometer or a strain gauge, measuring the resistance value of a metal which is converted into temperature or/and strain to measure the temperature or/and strain of the substrate, becomes less prone to the influence of noise or the like, which improves the precision of the measurements. In addition, by having a larger resistance value, the meander wiring unit can be reduced, allowing for measurements of temperature or/and strain in finer areas.

B) Since the undercoat film 11 is formed on the surface of the silicon wafer 10, then, the wiring pattern of the sensor 1 is traced and metalized using the dispersed nano-particle ink, strength of close contact of the dispersed nano-particle ink with the silicon wafer 10 becomes elevated compared to when no undercoat film 11 has been formed on the surface of the silicon wafer 10. In addition, the diffusion of the dispersed nano-particle ink into the silicon wafer 10 is suppressed. In addition, the growth of metal crystal particles contained in the dispersed nano-particle ink is suppressed, which stabilizes the resistance value when constitution has been performed as the sensor-fitted silicon wafer 100.

C) With substrates such as glass, even if tracing and metallization were performed by using a dispersed nano-particle ink, no metal contained in a dispersed nano-particle ink diffuses into the substrate. Thus, regarding such substrates, a wiring pattern of the sensor can be traced and metalized directly on the surface of the substrate.

D) sensor-fitted silicon wafer 100 with the wiring pattern of the sensor 1 traced and metalized thereon is treated by annealing at least a temperature employed at the time of the high-temperature process, or, while flowing a current in the wiring pattern of the sensor 1. The annealing treatment promotes the growth of metal crystal particles, and in addition, stabilizes unstable atoms present at the crystal boundary, causing the particle growth to reach an equilibrium state. This stabilizes the boundary energy, stabilizing the electric resistance value at the operating temperature when a sensor-fitted silicon wafer 100 has been constituted. Thus, a stable sensor-fitted silicon wafer 100 can be produced, in which a variation in the resistance value over time during the use of the sensor-fitted silicon wafer 100 is not likely to occur.

E) An overcoat-treatment is performed on the surface of the sensor-fitted silicon wafer 100 where a wiring pattern of the sensor 1 has been traced and metalized. This suppresses the growth of metal crystal particles contained in the dispersed nano-particle ink compared to when no overcoat-treatment has been performed on the surface of the sensor-fitted silicon wafer 100 surface, stabilizing the electric resistance value when the sensor-fitted silicon wafer 100 has been constituted. Furthermore, warping of the sensor-fitted silicon wafer 100 can be reduced in a similar manner. In addition, having become less prone to the influence of air convection in a similar manner, tearing of the wiring pattern of the sensor 1 can be suppressed.

F) The overcoat-treated sensor-fitted silicon wafer 100 is treated by annealing at least a temperature employed at the time of the high-temperature process, or, while flowing a current in the wiring pattern of the sensor 1. With this, compared to when no treatment by annealing has been performed on the overcoat-treated sensor-fitted silicon wafer 100, since a treatment by annealing is carried out after the overcoat-treatment, the overcoating material 13 can be stabilized, and the resistance value becomes stable when constitution has been performed the sensor-fitted silicon wafer 100. In addition, with a treatment by annealing carried out prior to overcoat-treatment, compared to treatment by annealing carried out after the overcoat-treatment, the line width of the wiring pattern is prone to becoming non-uniform due to movements of crystal particles, leading to a state in which the electric resistance value varies. By carrying out the treatment by annealing after the overcoat-treatment, the movements of crystal particles are suppressed, the line width of the wiring pattern becomes uniform, and the electric resistance value stabilizes without varying. In addition, by carrying out the treatment by annealing after the overcoat-treatment, the time needed for the treatment by annealing prior to the overcoat-treatment can be shortened.

Hereafter, each example will be described.

### Example 1

A material for an undercoat film 11 was coated over the surface of a silicon wafer 10 with a diameter of 300 mm using the spin-coat method (1000 rpm×30 sec) and dried by a 150° C.×1 hr heat-treatment. Next, a liquid-repellent diluted 50 folds with a solvent was coated over this undercoat film 11 using the spin-coat method (1000 rpm×30 sec) and dried by a 150° C.×1 hr heat-treatment. Next, using a dispersed nano-particle ink containing Ag, a wiring pattern was traced on the surface of the silicon wafer 10 where the liquid-repellent was dried. An ink jet device was used for tracing the wiring pattern.

Next, the silicon wafer 10 with the wiring pattern traced thereon was introduced into a ventilated oven heated to 230° C. to perform baking treatment of the dispersed nano-particle ink and metalize the dispersed nano-particle ink.

Through such steps, a sensor-fitted silicon wafer 100 such as the one shown in FIGS. 2A to 2C was produced, having a meander wiring unit at 29 locations. FIG. 2A shows the surface of the sensor-fitted silicon wafer 100, FIG. 2B shows enlarged an individual sensor 1 on the surface of the sensor-fitted silicon wafer 100 shown in FIG. 2A and FIG. 2C shows enlarged the meander wiring unit of the sensor 1 shown in FIG. 2B.

The sensor-fitted silicon wafer 100 was sent back and forth over a predetermined time between a cooling plate thermostated at 23° C. and a hot plate thermostated at 100° C. to measure the resistance value of the sensor 1 repeatedly. The measurement results are shown in FIG. 3. The horizontal axis in FIG. 3 is time (sec) and the vertical axis is the resistance value (Ω) of the sensor 1. As shown in FIG. 3, the peak values of the electric resistance value are confined to a range of 0.2Ω from 777.6Ω to 777.8Ω (corresponding to approximately 0.1° C. in temperature), revealing that there is only a slight error of approximately 0.1° C. or less to measure 100° C.

### Example 2

In Example 2, a dispersed nano-particle ink was baked and metalized through similar treatments to Example 1 described above.

After baking, annealing treatment was performed for a predetermined time at the operating temperature of the sensor-fitted silicon wafer 100 or higher (for example, 250° C.) while flowing current in the wiring pattern.

The produced sensor-fitted silicon wafer 100 was used and sent back and forth between a cooling plate thermostated at 23° C. and a hot plate thermostated at 100° C. to measure the resistance value of the sensor 1 repeatedly, similarly to Example 1.

As shown in FIG. 4, the peak values of the electric resistance value are confined to a range of 0.2Ω from 1,191.3Ω to 1,191.5Ω (corresponding to approximately 0.1° C. in temperature), revealing that there is only a slight error of approximately 0.1° C. or less to measure 100° C. However, when compared to Example 1, the electric resistance value has increased to measure the same 100° C., revealing that the stability of the electric resistance value has improved.

### Example 3

In Example 3, a dispersed nano-particle ink was baked and metalized through similar treatments to Example 1 described above.

After baking, as an overcoating material 13, a resin ink was coated over the wiring pattern by the spin-coat method and dried by a 150° C.×1 hr heat treatment.

When the produced sensor-fitted silicon wafer 100 was used to measure the characteristics thereof similarly to Example 1, similar results to FIG. 3 were obtained.

### Example 4

Example 4, a dispersed nano-particle ink was baked and metalized through similar treatments to Example 1 described above.

After baking, as an overcoating material 13, Al2O3 was coated over the wiring pattern by ion plating.

The produced sensor-fitted silicon wafer 100 was left alone on a covered hot plate thermostated at 250° C., which is representative of the temperature at the time of a high-temperature process, the variation over time in each resistance value from the sensor 1 and 2 at two locations traced over the same wafer 10 was measured repeatedly. The measurement results are shown in FIG. 5. The horizontal axis in FIG. 5 is time (hr) and the vertical axis is each resistance value Ag1 and Ag2 (kΩ) from the sensor 1 and 2 at two locations traced over the same wafer 10. Note that the measured data were grouped hour by hour, type A uncertainty was calculated based on JIS Z8404, and the error bars were represented with K=2. For both of each resistance value Ag1 and Ag2, the resistance value shifts within the error range for at least 100 hours, revealing that the dispersed nano-particle ink is stable without changing over time due to heat. Note that similar characteristics were also obtained when AlN and SiO2 were used for the overcoating material 13.

### Example 5

Similarly to Example 1, an undercoat film 11 was formed on the surface of the silicon wafer 10. The undercoat film 11 was formed by a combination of silane coupling and Ni plating.

After the undercoat film 11 was formed, a dispersed nano-particle ink containing Ag was used to trace a wiring pattern, and the dispersed nano-particle ink was baked and metalized through similar steps to Example 1.

Next, portions of the Ni plating film that were not in close contact with the wiring pattern were eliminated by plasma etching.

When the produced sensor-fitted silicon wafer 100 was used to measure the characteristics thereof similarly to Example 1, results similar to FIG. 3 were obtained.

### Example 6

As the dispersed nano-particle ink, one comprising Pd diffused into Ag was used. The steps for producing the sensor-fitted silicon wafer 100 were carried out similarly to FIGS. 1A to 1D.

When the produced sensor-fitted silicon wafer 100 was used to measure the characteristics thereof similarly to Example 1, results similar to FIG. 3 were obtained.

### Example 7

Similarly to Example 4, after the overcoat-treatment was carried out, a treatment by annealing was carried out for a predetermined time at the operating temperature of the sensor-fitted silicon wafer 100 or higher while flowing a current in the wiring pattern.

When the produced sensor-fitted silicon wafer 100 was used to measure the characteristics thereof similarly to Example 4, results similar to FIG. 5 were obtained.

### BRIEF DESCRIPTION OF THE DRAWINGS

FIGS. 1A, 1B, 1C and 1D are figures showing the cross-section of the sensor-fitted silicon wafer of the examples at each production step.

FIGS. 2A, 2B and 2C are figures showing a sensor-fitted silicon wafer having a meander wiring unit at 29 locations, FIG. 2A being a figure showing the surface of the sensor-fitted silicon wafer, FIG. 2B being a figure showing enlarged an individual sensor on the surface of the sensor-fitted silicon wafer shown in FIG. 2A, and FIG. 2C being a figure showing enlarged a meander wiring unit of the sensor shown in FIG. 2B.

FIG. 3 is a graph showing the results of sending, after baking treatment, a sensor-fitted silicon wafer back and forth between a cooling plate thermostated at 23° C. and a hot plate thermostated at 100° C. to measure the resistance value of the sensor 1 repeatedly.

FIG. 4 is a graph showing the results of sending, after annealing treatment, a sensor-fitted silicon wafer back and forth between a cooling plate thermostated at 23° C. and a hot plate thermostated at 100° C. to measure the resistance value of the sensor 1 repeatedly.

FIG. 5 is a graph showing the results of leaving, after overcoat-treatment, a sensor-fitted silicon wafer on a covered hot plate thermostated at 250° C., which is representative of the temperature at the time of a high-temperature process, to measure repeatedly the variation over time in each resistance value of the sensors at two locations traced over the same wafer.

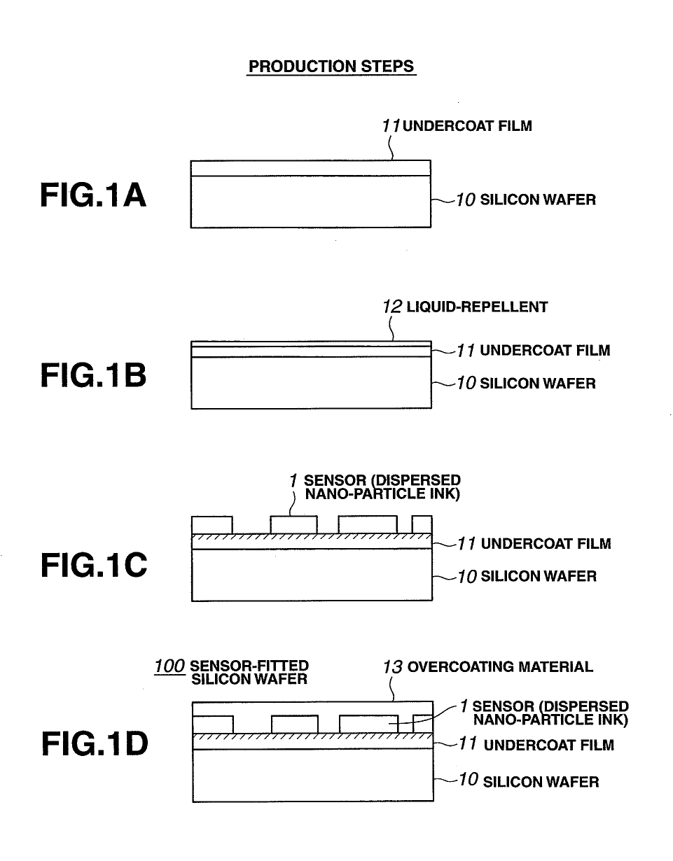

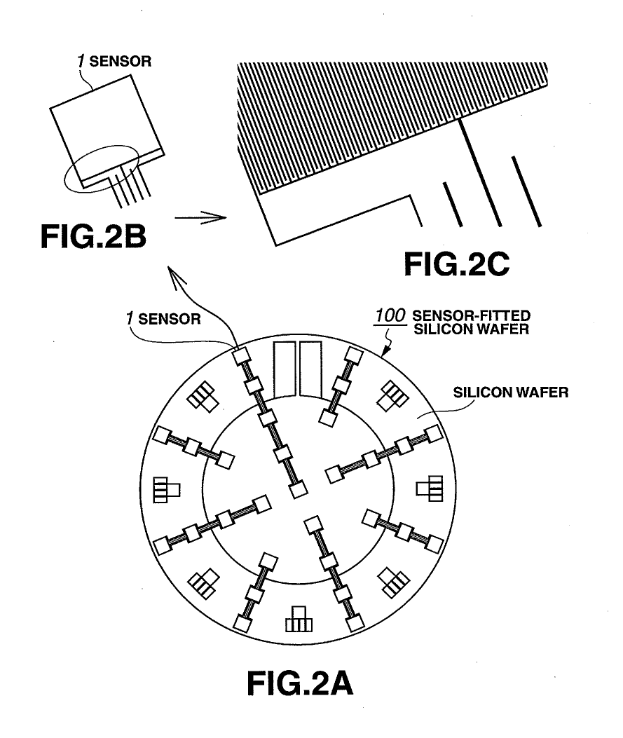

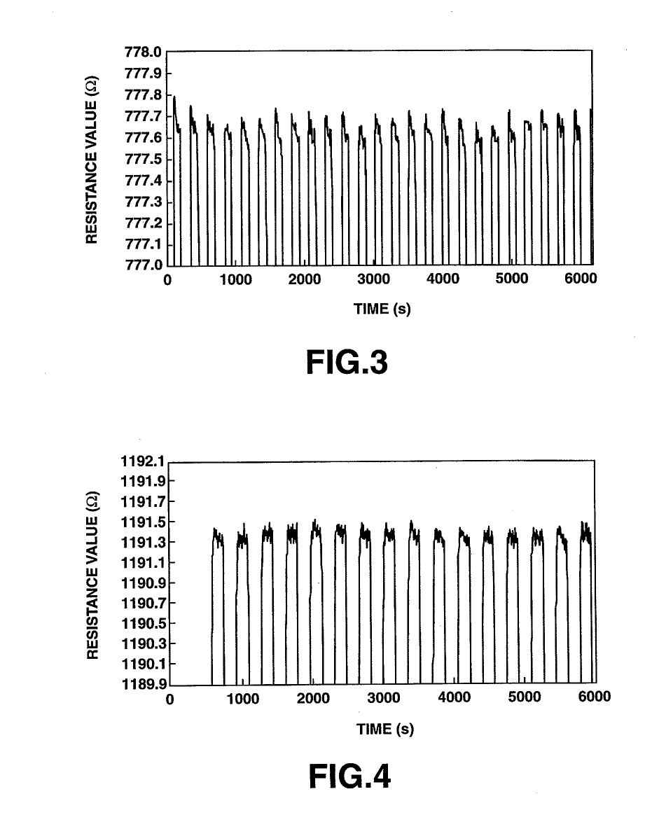

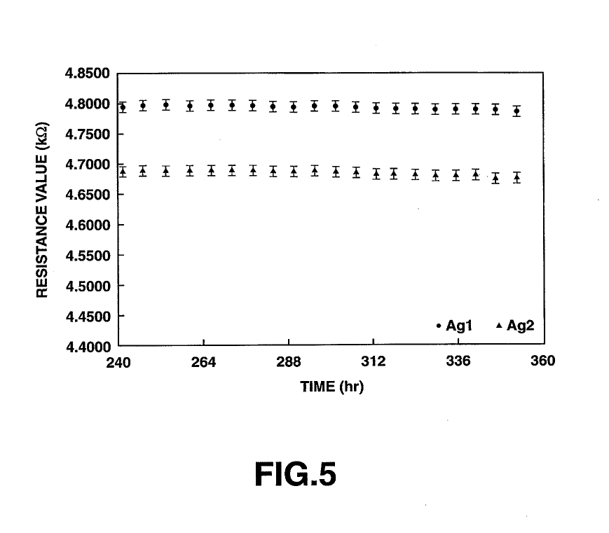

1. A sensor-fitted substrate having a sensor over a substrate for measuring a temperature or/and strain of the substrate in a high-temperature process, wherein
the sensor measures a resistance value of a metal serving as a resistor which is converted into a temperature or/and strain, thereby measuring the temperature or/and strain of the substrate,
the substrate is a substrate where metals are diffused, the metals being contained in a dispersed nano-particle ink of nano-particles of any metal among Au, Ag, Pt, Ni and Cu or alloy nano-particles containing Pd or Cu or Si in Ag or a dispersed nano-particle ink in which Ag nano-particles and nano-particles of Pd or Cu or Si are mixed,
an undercoat film is formed on a surface of the substrate, the film being configured, compared to when no undercoat film is formed on the surface, to allow a strength of close contact of the dispersed nano-particle ink with the substrate to be increased, the diffusion of the dispersed nano-particle ink into the substrate to be suppressed, and the growth of metal crystal particles contained in the dispersed nano-particle ink to be suppressed,
a wiring pattern of the sensor is traced on the surface of the undercoat film of the substrate surface using the dispersed nano-particle ink, with the dispersed nano-particle ink being baked and metalized.

2. The sensor-fitted substrate comprising claim 1, wherein the substrate is silicon wafer or GaAs or GaP or any metal from Al, Cu, Fe, Ti and SUS or carbon.

3. A sensor-fitted substrate having a sensor over a substrate for measuring a temperature or/and strain of the substrate in a high-temperature process, wherein
the sensor measures a resistance value of a metal serving as a resistor which is converted into a temperature, thereby measuring the temperature or/and strain of the substrate,
the substrate is a substrate where metals are not diffused, the metals being contained in a dispersed nano-particle ink of nano-particles of any metal among Au, Ag, Pt, Ni and Cu or alloy nano-particles containing Pd or Cu or Si in Ag or a dispersed nano-particle ink in which Ag nano-particles and nano-particles of Pd or Cu or Si are mixed, and wherein
a wiring pattern of the sensor is traced on the surface of the substrate, by coating directly with the dispersed nano-particle ink, with the dispersed nano-particle ink being baked and metalized.

4. The sensor-fitted substrate according to claim 3, wherein the substrate is glass or quartz glass or sapphire or ceramic or polyimide or Teflon or epoxy or a fiber reinforced material of these plastics.

5. A sensor-fitted substrate having a sensor over a substrate for measuring a temperature or/and strain of the substrate in a high-temperature process, wherein
the sensor measures a resistance value of the metal serving as a resistor which is converted into a temperature or/and strain, thereby measuring the temperature or/and strain of the substrate,
a wiring pattern of the sensor is traced on the surface of the substrate by coating with a dispersed nano-particle ink of nano-particles of any metal among Au, Ag, Pt, Ni and Cu or alloy nano-particles containing Pd or Cu or Si in Ag or a dispersed nano-particle ink in which Ag nano-particles and nano-particles of Pd or Cu or Si are mixed, with the dispersed nano-particle ink being baked an metalized, and wherein
the substrate with the wiring pattern of the sensor traced and metalized thereon is treated by annealing at least a temperature employed at the time of the high-temperature process, or, while flowing a current in the wiring pattern of the sensor.

6. The sensor-fitted substrate according to claim 1, wherein the substrate with the wiring pattern of the sensor traced and metalized thereon is treated by annealing at least a temperature employed at the time of the high-temperature process, or, while flowing a current in the wiring pattern of the sensor.

7. The sensor-fitted substrate according to claim 3, wherein the substrate with the wiring pattern of the sensor traced and metalized thereon is treated by annealing at least a temperature employed at the time of the high-temperature process, or, while flowing a current in the wiring pattern of the sensor.

8. A sensor-fitted substrate having a sensor over a substrate for measuring a temperature or/and strain of the substrate in a high-temperature process, wherein
the sensor measures a resistance value of a metal serving as a resistor which is converted into a temperature or/and strain, thereby measuring the temperature or/and strain of the substrate,
a wiring pattern of the sensor is traced on the surface of the substrate by coating with a dispersed nano-particle ink of nano-particles of any metal among Au, Ag, Pt, Ni and Cu or alloy nano-particles containing Pd or Cu or Si in Ag or a dispersed nano-particle ink in which Ag nano-particles and nano-particles of Pd or Cu or Si are mixed, with the dispersed nano-particle ink being baked and metalized, and
an overcoat-treatment is performed on the surface of the substrate with the wiring pattern of the sensor traced and metalized thereon, the treatment being employed, compared to when no overcoat-treatment is performed on this substrate surface, to allow growth of metal crystal particles contained in the dispersed nano-particle ink to be suppressed, the warping of the substrate to be reduced, and to induce the substrate to become less prone to the influence of air convection, and moreover to allow tearing of the wiring pattern of the sensor to be suppressed.

9. The sensor-fitted substrate according to claim 1, wherein an overcoat-treatment is performed on the surface of the substrate with the wiring pattern of the sensor traced and metalized thereon, the treatment being employed, compared to when no overcoat-treatment is performed on this substrate surface, to allow growth of metal crystal particles contained in the dispersed nano-particle ink to be suppressed, warping of the substrate to be reduced, and to induce the substrate to become less prone to the influence of air convection, and moreover allow tearing of the wiring pattern of the sensor to be suppressed.

10. The sensor-fitted substrate according to claim 3, wherein an overcoat-treatment is performed on the surface of the substrate with the wiring pattern of the sensor traced and metalized thereon, the treatment being employed, compared to when no overcoat-treatment is performed on this substrate surface, to allow growth of metal crystal particles contained in the dispersed nano-particle ink to be suppressed, warping of the substrate to be reduced, and to induce the substrate to become less prone to the influence of air convection, and moreover allow tearing of the wiring pattern of the sensor to be suppressed.

11. The sensor-fitted substrate comprising claim 5, wherein an overcoat-treatment is performed on the surface of the substrate with the wiring pattern of the sensor traced and metalized thereon and treated by annealing, the treatment being employed, compared to when no overcoat-treatment is performed on this substrate surface, to allow growth of metal crystal particles contained in the dispersed nano-particle ink to be suppressed, warping of the substrate to be reduced, and to induce the substrate to become less prone to the influence of air convection, and moreover to allow tearing of the wiring pattern of the sensor to be suppressed.

12. The sensor-fitted substrate according to claim 6, wherein an overcoat-treatment is performed on the surface of the substrate with the wiring pattern of the sensor traced and metalized thereon and treated by annealing, the treatment being employed, compared to when no overcoat-treatment has been performed on this substrate surface, to allow growth of metal crystal particles contained in the dispersed nano-particle ink to be suppressed, warping of the substrate to be reduced, and to induce the substrate to become less prone to the influence of air convection, and moreover to allow tearing of the wiring pattern of the sensor to be suppressed.

13. The sensor-fitted substrate according to claim 7, wherein an overcoat-treatment is performed on the surface of the substrate with the wiring pattern of the sensor traced and metalized thereon and treated by annealing, the treatment being employed, compared to when no overcoat-treatment is performed on this substrate surface, to allow growth of metal crystal particles contained in the dispersed nano-particle ink to be suppressed, warping of the substrate to be reduced, and to induce the substrate to become less prone to the influence of air convection, and moreover to allow tearing of the wiring pattern of the sensor to be suppressed.

14. A sensor-fitted substrate having a sensor over a substrate for measuring a temperature or/and strain of the substrate in a high-temperature process, wherein
the sensor measures a resistance value of a metal serving as a resistor which is converted into a temperature or/and strain, thereby measuring the temperature or/and strain of the substrate,
a wiring pattern of the sensor is traced on the surface of the substrate by coating with a dispersed nano-particle ink of nano-particles of any metal among Au, Ag, Pt, Ni and Cu or alloy nano-particles containing Pd or Cu or Si in Ag or a dispersed nano-particle ink in which Ag nano-particles and nano-particles of Pd or Cu or Si are mixed, with the dispersed nano-particle ink being baked and metalized,
an overcoat-treatment is performed on the surface of the substrate with the wiring pattern of the sensor traced and metalized thereon, the treatment being employed, compared to when no overcoat-treatment is performed on this substrate surface, to allow growth of metal crystal particles contained in the dispersed nano-particle ink to be suppressed, warping of the substrate to be reduced, and to induce the substrate to become less prone to the influence of air convection, and moreover to allow tearing of the wiring pattern of the sensor to be suppressed, and
the overcoat-treated substrate is treated by annealing at least a temperature employed at the time of the high-temperature process, or, while flowing a current in the wiring pattern of the sensor.

15. The sensor-fitted substrate according to claim 9, wherein the overcoat-treated substrate is treated by annealing at a temperature at least a temperature employed at the time of the high-temperature process, or, while flowing a current in the wiring pattern of the sensor.

16. The sensor-fitted substrate according to claim 10, wherein the overcoat-treated substrate is treated by annealing at least a temperature employed at the time of the high-temperature process, or, while flowing a current in the wiring pattern of the sensor.

17. The sensor-fitted substrate according to claim 11, wherein the overcoat-treated substrate is treated by annealing at least a temperature employed at the time of the high-temperature process, or, while flowing a current in the wiring pattern of the sensor.

18. The sensor-fitted substrate according to claim 12, wherein the overcoat-treated substrate is treated by annealing at least a temperature employed at the time of the high-temperature process, or, while flowing a current in the wiring pattern of the sensor.

19. The sensor-fitted substrate according to claim 13, wherein the overcoat-treated substrate is treated by annealing at least a temperature employed at the time of the high-temperature process, or, while flowing a current in the wiring pattern of the sensor.

20. A method for producing a sensor-fitted substrate having a sensor over a substrate for measuring a temperature or/and strain of the substrate in a high-temperature process, wherein
the sensor measures a resistance value of a metal serving as a resistor which is converted into a temperature or/and strain, thereby measuring the temperature or/and strain of the substrate, and
the substrate is a substrate where metals are diffused, the metals being contained in a dispersed nano-particle ink of nano-particles of any metal among Au, Ag, Pt, Ni and Cu or alloy nano-particles containing Pd or Cu or Si in Ag or a dispersed nano-particle ink in which Ag nano-particles and nano-particles of Pd or Cu or Si are mixed,
the method comprising:
a step of forming an undercoat film on the surface of the substrate, the film being configured, compared to when no undercoat film is formed, to allow a strength of close contact of the dispersed nano-particle ink with the substrate to be increased, diffusion of the dispersed nano-particle ink into the substrate to be suppressed, and growth of metal crystal particles contained in the dispersed nano-particle ink to be suppressed;
a step of forming a wiring pattern of the sensor on the surface of the undercoat film of the substrate surface by using the dispersed nano-particle ink; and
a step of firing and metalizing the dispersed nano-particle ink.

21. A method for producing a sensor-fitted substrate having a sensor over a substrate for measuring a temperature or/and strain of the substrate in a high-temperature process, wherein
the sensor measures a resistance value of a metal serving as a resistor which is converted into a temperature or/and strain, thereby measuring the temperature or/and strain of the substrate, and
the substrate is a substrate where metals are not diffused, the metals being contained in a dispersed nano-particle ink of nano-particles of any metal among Au, Ag, Pt, Ni and Cu or alloy nano-particles containing Pd or Cu or Si in Ag or a dispersed nano-particle ink in which Ag nano-particles and nano-particles of Pd or Cu or Si are mixed,
the method comprising:
a step of forming a wiring pattern of the sensor by coating directly with the dispersed nano-particle ink; and
a step of firing and metalizing the dispersed nano-particle ink.

22. A method for producing a sensor-fitted substrate having a sensor over a substrate for measuring a temperature or/and strain of the substrate in a high-temperature process, wherein
the sensor measures a resistance value of a metal serving as a resistor which is converted into a temperature or/and strain, thereby measuring the temperature or/and strain of the substrate, and
the substrate is a substrate where metals are diffused, the metals being contained in a dispersed nano-particle ink of nano-particles of any metal among Au, Ag, Pt, Ni and Cu or alloy nano-particles containing Pd or Cu or Si in Ag or a dispersed nano-particle ink in which Ag nano-particles and nano-particles of Pd or Cu or Si are mixed,
the method comprising:
a step of forming an undercoat film on the surface of the substrate, the film being configured, compared to when no undercoat film is formed, to allow a strength of close contact of the dispersed nano-particle ink with the substrate to be increased, diffusion of the dispersed nano-particle ink into the substrate to be suppressed, and growth of metal crystal particles contained in the dispersed nano-particle ink to be suppressed;
a step of forming a wiring pattern of the sensor on the surface of the undercoat film of the substrate surface by using the dispersed nano-particle ink;
a step of firing and metalizing the dispersed nano-particle ink, and
the step of treating by annealing the substrate with the wiring pattern of the sensor traced and metalized thereon at least a temperature employed at the time of the high-temperature process, or, while flowing a current in the wiring pattern of the sensor.

23. A method for producing a sensor-fitted substrate having a sensor over a substrate for measuring a temperature or/and strain of the substrate in a high-temperature process, wherein
the sensor measures a resistance value of a metal serving as a resistor which is converted into a temperature or/and strain, thereby measuring the temperature or/and strain of the substrate, and
the substrate is a substrate where metals are not diffused, the metals being contained in a dispersed nano-particle ink of nano-particles of any metal among Au, Ag, Pt, Ni and Cu or alloy nano-particles containing Pd or Cu or Si in Ag or a dispersed nano-particle ink in which Ag nano-particles and nano-particles of Pd or Cu or Si are mixed,
the method comprising:
a step of forming a wiring pattern of the sensor by coating directly with the dispersed nano-particle ink;
a step of firing and metalizing the dispersed nano-particle ink; and
a step of treating by annealing the substrate with the wiring pattern of the sensor traced and metalized thereon at least a temperature employed at the time of the high-temperature process, or, while flowing a current in the wiring pattern of the sensor.

24. A method for producing a sensor-fitted substrate having a sensor over a substrate for measuring a temperature or/and strain of the substrate in a high-temperature process, wherein
the sensor measures a resistance value of a metal serving as a resistor which is converted into a temperature or/and strain, thereby measuring the temperature or/and strain of the substrate, and
the substrate is a substrate where metals are diffused, the metals being contained in a dispersed nano-particle ink of nano-particles of any metal among Au, Ag, Pt, Ni and Cu or alloy nano-particles containing Pd or Cu or Si in Ag or a dispersed nano-particle ink in which Ag nano-particles and nano-particles of Pd or Cu or Si are mixed,
the method comprising:
a step of forming an undercoat film on the surface of the substrate, the film being configured, compared to when no undercoat film has been formed, to allow a strength of close contact of the dispersed nano-particle ink with the substrate to be increased, diffusion of the dispersed nano-particle ink into the substrate to be suppressed, and growth of metal crystal particles contained in the dispersed nano-particle ink to be suppressed;
a step of forming a wiring pattern of the sensor on the surface of the undercoat film of the substrate surface by using the dispersed nano-particle ink;
a step of firing and metalizing the dispersed nano-particle ink;
a step of treating by annealing the substrate with the wiring pattern of the sensor traced and metalized thereon at least a temperature employed at the time of the high-temperature process, or, while flowing a current in the wiring pattern of the sensor; and
a step of performing an overcoat-treatment on the surface of the substrate with the wiring pattern of the sensor traced and metalized thereon and treated by annealing, the treatment being employed, compared to when no overcoat-treatment is performed on this substrate surface, to allow growth of metal crystal particles contained in the dispersed nano-particle ink to be suppressed, warping of the substrate to be reduced, and to induce the substrate to become less prone to the influence of air convection, and moreover to allow tearing of the wiring pattern of the sensor to be suppressed.

25. A method for producing a sensor-fitted substrate having a sensor over a substrate for measuring a temperature or/and strain of the substrate in a high-temperature process, wherein
the sensor measures a resistance value of a metal serving as a resistor which is converted into a temperature or/and strain, thereby measuring the temperature or/and strain of the substrate, and
the substrate is a substrate where metals are not diffused, the metals being contained in a dispersed nano-particle ink of nano-particles of any metal among Au, Ag, Pt, Ni and Cu or alloy nano-particles containing Pd or Cu or Si in Ag or a dispersed nano-particle ink in which Ag nano-particles and nano-particles of Pd or Cu or Si are mixed,
the method comprising:
a step of forming on the surface of the substrate a wiring pattern of the sensor by coating directly with the dispersed nano-particle ink;
a step of firing and metalizing the dispersed nano-particle ink;
a step of treating by annealing the substrate with the wiring pattern of the sensor traced and metalized thereon at least a temperature employed at the time of the high-temperature process, or, while flowing a current in the wiring pattern of the sensor; and
a step of performing an overcoat-treatment on the surface of the substrate with the wiring pattern of the sensor traced and metalized thereon and treated by annealing, the treatment being employed, compared to when no overcoat-treatment is performed on this substrate surface, to allow growth of metal crystal particles contained in the dispersed nano-particle ink to be suppressed, warping of the substrate to be reduced, and to induce the substrate to become less prone to the influence of air convection, and moreover to allow tearing of the wiring pattern of the sensor to be suppressed.

26. A method for producing a sensor-fitted substrate having a sensor over a substrate for measuring a temperature or/and strain of the substrate in a high-temperature process, wherein
the sensor measures a resistance value of a metal serving as a resistor which is converted into a temperature or/and strain, thereby measuring the temperature or/and strain of the substrate, and
the substrate is a substrate where metals are diffused, the metals being contained in a dispersed nano-particle ink of nano-particles of any metal among Au, Ag, Pt, Ni and Cu or alloy nano-particles containing Pd or Cu or Si in Ag or a dispersed nano-particle ink in which Ag nano-particles and nano-particles of Pd or Cu or Si are mixed,
the method comprising:
a step of forming an undercoat film on the surface of the substrate, the film being configured, compared to when no undercoat film is formed, to allow a strength of close contact of the dispersed nano-particle ink with the substrate to be increased, diffusion of the dispersed nano-particle ink into the substrate to be suppressed, and growth of metal crystal particles contained in the dispersed nano-particle ink to be suppressed;
a step of forming a wiring pattern of the sensor on the surface of the undercoat film of the substrate surface by using the dispersed nano-particle ink;
a step of firing and metalizing the dispersed nano-particle ink;
a step of performing an overcoat-treatment on the surface of the substrate with the wiring pattern of the sensor traced and metalized thereon, the treatment being employed, compared to when no overcoat-treatment is performed on this substrate surface, to allow growth of metal crystal particles contained in the dispersed nano-particle ink to be suppressed, warping of the substrate to be reduced, and to induce the substrate to become less prone to the influence of air convection, and moreover to allow tearing of the wiring pattern of the sensor to be suppressed; and
a step of treating by annealing the overcoat-treated substrate at least a temperature employed at the time of the high-temperature process, or, while flowing a current in the wiring pattern of the sensor.

27. A method for producing a sensor-fitted substrate having a sensor over a substrate for measuring a temperature or/and strain of the substrate in a high-temperature process, wherein
the sensor measures a resistance value of a metal serving as a resistor which is converted into a temperature or/and strain, thereby measuring the temperature or/and strain of the substrate, and
the substrate is a substrate where metals are diffused, the metals being contained in a dispersed nano-particle ink of nano-particles of any metal among Au, Ag, Pt, Ni and Cu or alloy nano-particles containing Pd or Cu or Si in Ag or a dispersed nano-particle ink in which Ag nano-particles and nano-particles of Pd or Cu or Si are mixed,
the method comprising:
a step of forming a wiring pattern of the sensor by coating directly with the dispersed nano-particle ink;
a step of firing and metalizing the dispersed nano-particle ink;
a step of performing an overcoat-treatment on the surface of the substrate with the wiring pattern of the sensor traced and metalized thereon, the treatment being employed, compared to when no overcoat-treatment is performed on this substrate surface, to allow growth of metal crystal particles contained in the dispersed nano-particle ink to be suppressed, warping of the substrate to be reduced, and to induce the substrate to become less prone to the influence of air convection, and moreover to allow tearing of the wiring pattern of the sensor to be suppressed; and
a step of treating by annealing the overcoat-treated substrate at least a temperature employed at the time of the high-temperature process, or, while flowing a current in the wiring pattern of the sensor.

28. A method for producing a sensor-fitted substrate having a sensor over a substrate for measuring a temperature or/and strain of the substrate in a high-temperature process, wherein
the sensor measures a resistance value of a metal serving as a resistor which is converted into a temperature or/and strain, thereby measuring the temperature or/and strain of the substrate, and
the substrate is a substrate where metals are diffused, the metals being contained in a dispersed nano-particle ink of nano-particles of any metal among Au, Ag, Pt, Ni and Cu or alloy nano-particles containing Pd or Cu or Si in Ag or a dispersed nano-particle ink in which Ag nano-particles and nano-particles of Pd or Cu or Si are mixed,
the method comprising:
a step of forming an undercoat film on the surface of the substrate, the film being configured, compared to when no undercoat film is formed, to allow a strength of close contact of the dispersed nano-particle ink with the substrate to be increased, diffusion of the dispersed nano-particle ink into the substrate to be suppressed, and growth of metal crystal particles contained in the dispersed nano-particle ink to be suppressed;
a step of forming a wiring pattern of the sensor on the surface of the undercoat film of the substrate surface by using the dispersed nano-particle ink;
a step of firing and metalizing the dispersed nano-particle ink;
a step of treating by annealing the substrate with the wiring pattern of the sensor traced and metalized thereon at least a temperature employed at the time of the high-temperature process, or, while flowing a current in the wiring pattern of the sensor; and
a step of performing an overcoat-treatment on the surface of the substrate with the wiring pattern of the sensor traced and metalized thereon and treated by annealing, the treatment being employed, compared to when no overcoat-treatment is performed on this substrate surface, to allow growth of metal crystal particles contained in the dispersed nano-particle ink to be suppressed, warping of the substrate to be reduced, and to induce the substrate to become less prone to the influence of air convection, and moreover to allow tearing of the wiring pattern of the sensor to be suppressed; and
a step of treating by annealing the overcoat-treated substrate at least a temperature employed at the time of the high-temperature process, or, while flowing a current in the wiring pattern of the sensor.

29. A method for producing a sensor-fitted substrate having a sensor over a substrate for measuring a temperature or/and strain of the substrate in a high-temperature process, wherein
the sensor measures a resistance value of a metal serving as a resistor which is converted into a temperature or/and strain, thereby measuring the temperature or/and strain of the substrate, and
the substrate is a substrate where metals are not diffused, the metals being contained in a dispersed nano-particle ink of nano-particles of any metal among Au, Ag, Pt, Ni and Cu or alloy nano-particles containing Pd or Cu or Si in Ag or a dispersed nano-particle ink in which Ag nano-particles and nano-particles of Pd or Cu or Si are mixed,
the method comprising:
a step of forming on the surface of the substrate a wiring pattern of the sensor by coating directly with the dispersed nano-particle ink;
a step of firing and metalizing the dispersed nano-particle ink;
a step of treating by annealing the substrate with the wiring pattern of the sensor traced and metalized thereon at least a temperature employed at the time of the high-temperature process, or, while flowing a current in the wiring pattern of the sensor;
a step of performing an overcoat-treatment on the surface of the substrate with the wiring pattern of the sensor traced and metalized thereon and treated by annealing, the treatment being employed, compared to when no overcoat-treatment is performed on this substrate surface, to allow growth of metal crystal particles contained in the dispersed nano-particle ink to be suppressed, warping of the substrate to be reduced, and to induce the substrate to become less prone to the influence of air convection, and moreover to allow tearing of the wiring pattern of the sensor to be suppressed; and
a step of treating by annealing the overcoat-treated substrate at least a temperature employed at the time of the high-temperature process, or, while flowing a current in the wiring pattern of the sensor.
